(19) United States
(12) Patent Application Publication
(10) Pub. No.: US 2014/0264314 A1
(43) Pub. Date: Sep. 18, 2014

(54) METHOD FOR MANUFACTURING ORGANIC SEMICONDUCTOR ELEMENT, SEMICONDUCTOR ELEMENT, AND ELECTRONIC APPARATUS

(71) Applicant: Sony Corporation, Tokyo (JP)

(72) Inventors: Osamu Goto, Kanagawa (JP); Yosuke Murakami, Kanagawa (JP)

(73) Assignee: Sony Corporation, Minato-ku, Tokyo (JP)

(21) Appl. No.: 14/354,062

(22) PCT Filed: Oct. 26, 2012
(86) PCT No.: PCT/JP2012/006894

§ 371 Date: Apr. 24, 2014

(30) Foreign Application Priority Data
Nov. 4, 2011 (JP) 2011-242461

(51) Int. Cl. H01L 51/05; H01L 27/28; H01L 51/00

(52) U.S. Cl. CPC H01L 51/0558; H01L 51/0096; H01L 27/283
USPC 257/40

(57) ABSTRACT

An organic single crystal thin film includes an organic single crystal formed on a substrate across a boundary between a first region of the substrate and a second region of the substrate that is adjacent to the first region. The first region has a different shape or size than the second region.

### TECHNICAL FIELD

The present disclosure relates to a method for manufacturing an organic semiconductor element, an organic semiconductor element, and an electronic apparatus. For example, the present disclosure relates to a method for manufacturing an organic transistor by using an organic semiconductor single crystal thin film, an organic transistor, and an electronic apparatus by using this organic transistor.

### BACKGROUND ART

Hitherto, as for a method for manufacturing an organic transistor, the following method has been proposed (refer to NPL 1). That is, an organic solution, in which an organic semiconductor and an insulating polymer are dissolved in an organic solvent, is applied to a substrate through spin coating and, thereafter, baking is performed. It is stated that in this manner, the organic semiconductor and the polymer are phase-separated and, thereby, a good organic semiconductor thin film/insulating film interface can be formed without exposure to the air and the carrier mobility is improved.

### CITATION LIST

### Patent Literature

PTL 1: Japanese Unexamined Patent Application Publication No. 2010-6794

### Non Patent Literature

NPL 1: Richard Hamilton, Jeremy Smith, Simon Ogier, Martin Heeney, John E. Anthony, lain McCulloch, Janos Veres, Donal D. C. Bradley, and Thomas D. Anthopoulos: Adv. Mater, 2009, 21, 1166-1171
NPL 2: N. Kobayashi, M. Sasaki and K. Nomoto: Chem. Mater. 21 (2009) 552

### SUMMARY OF INVENTION

### Technical Problem

However, it is difficult for the method for manufacturing an organic transistor in the related art proposed in NPL 1 to grow an organic semiconductor single crystal thin film and, therefore, it has not been able to produce an organic transistor having an organic semiconductor single crystal thin film/insulating film interface.

Accordingly, an issue to be solved by the present disclosure is to provide a method for manufacturing an organic semiconductor element, wherein an organic semiconductor element having a good organic semiconductor single crystal thin film/insulating film interface can be produced, and the organic semiconductor element.

Another issue to be solved by the present disclosure is to provide an electronic apparatus by using the above-described organic semiconductor element.

### Solution to Problem

In an embodiment, an organic single crystal thin film is provided and includes an organic single crystal formed on a substrate across a boundary between a first region of the substrate and a second region of the substrate that is adjacent to the first region, the first region having a different shape or size than the second region.

In another embodiment, a method of manufacturing an organic single crystal thin film is provided. The method includes forming an organic single crystal across a boundary between a first region of the substrate and a second region of the substrate that is adjacent to the first region, the first region having a different shape or size than the second region.

In another embodiment, an organic single crystal thin film array is provided, and includes a plurality of organic single crystals arranged in an array, each organic single crystal being formed across boundaries between a first region of a substrate, and second regions of the substrate that are adjacent to the first region, the first region having a different shape or size than each of the respective second regions.

In another embodiment, a method of manufacturing an organic single crystal thin film array is provided. The method includes forming a plurality of organic single crystals across boundaries between a first region of a substrate, and second regions of the substrate that are adjacent to the first region, the first region having a different shape or size than each of the respective second regions.

In another embodiment, a semiconductor device in provided and includes: a gate electrode disposed on a substrate; an insulating film formed on a portion of the substrate outside of the gate electrode; and an organic single crystal thin film formed on the gate electrode and the insulating film, the organic single crystal thin film including an organic single crystal formed on a substrate across a boundary between a first region of the substrate and a second region of the substrate that is adjacent to the first region, the first region having a different shape or size than the second region.

In another embodiment, a crystal growth substrate is provided and includes a first surface region configured to gather an amount of liquid relative to a surrounding second surface region due to a liquiphillic characteristic of the first surface region relative to a surrounding second surface region. In this embodiment, the first surface region includes first and second sub-regions each configured to retain a different volume of liquid per unit surface area of the respective sub-region.

In another embodiment, a method of distributing a liquid is provided. The method includes applying the liquid to a substrate and allowing the liquid to gather in a first surface region of the substrate, the first surface region having a liquiphillic characteristic relative to a surrounding second surface region of the substrate. In this embodiment, the first surface region includes first and second sub-regions each configured to retain a different volume of liquid per unit surface area of the respective sub-region.

In another embodiment, a method of concentrating a liquid solution is provided. The method includes applying the solution to a substrate and allowing the liquid to gather in a first surface region of the substrate, the first surface region having a liquiphillic characteristic relative to a surrounding second surface region of the substrate, the first surface region including first and second sub-regions each configured to retain a different volume of liquid per unit surface area of the respective sub-region. The method also includes evaporating a portion of the solution to increase concentrations of the solution retained in the sub-regions at different rates corresponding to the volume of liquid per unit surface area ratios of the respective sub-regions.

In the present disclosure, typically, a region outside the growth control region and the nucleation control region on the one principal surface of the base substance is specified to be a lyophobic surface. Consequently, in the case where an organic solution is supplied to the growth control region and the nucleation control region, the organic solution can be held on only these growth control region and nucleation control region reliably.

Typically, the nucleation control region has the shape of, for example, a straight-line nearly perpendicular to one side of the growth control region, concretely, inclined at an angle of 90°±10° relative to the one side of the growth control region. Alternatively, the nucleation control region includes a first portion, which is coupled to the growth control region and which has the shape of a straight-line inclined at an angle of 90°±10° relative to the above-described one side of the growth control region, and a second portion, which is coupled to the first portion and which has the shape of a straight-line inclined relative to the above-described one side. The second portion is, for example, inclined relative to the above-described one side of the growth control region at an angle of 0° or more and 90° or less, for example, 25° or more and 65° or less. The width of the nucleation control region is, for example, generally 0.1 μm or more and 50 μm or less, favorably 1 μm or more and 50 μm or less, more favorably 1 μm or more and 30 μm or less, and further favorably 1 μm or more and 20 μm or less or 1 μm or more and 10 μm or less, although not limited to this. The shape of the growth control region is selected as necessary, but is typically the shape of a rectangle or a square.

Favorably, the size of the growth control region is selected so as to become sufficiently large as compared with the size of the nucleation control region. As a typical example, the growth control region has the shape of a rectangle and the nucleation control region has the shape of a rectangle which is disposed on one side of the growth control region perpendicularly to this side and which is smaller than the above-described growth control region. Typically, the growth control region has the shape of a rectangle with the length of the above-described one side of 1,000 μm or more and 10,000 μm or less and the length of another side of 100 μm or more and 800 μm or less and is sufficiently large as compared with the nucleation control region.

Typically, the solvent in the organic solution is vaporized in such a way that the state of the organic solution in the growth control region is in a metastable state between a solubility curve and a supersolubility curve of the solubility-supersolubility diagram of the organic solution and the state of the organic solution in the nucleation control region is in an unstable region under the supersolubility curve of the solubility-supersolubility diagram. That is, the organic solution immediately after being supplied to the growth control region and the nucleation control region is specified to be in the stable region above the solubility curve of the solubility-supersolubility diagram, although in the process of vaporization of the solvent of the organic solution, the state of the organic solution in the growth control region is specified to be in a metastable state between the solubility curve and the supersolubility curve of the solubility-supersolubility diagram and the state of the organic solution in the nucleation control region is specified to be in an unstable region under the supersolubility curve. This state can be realized easily by selecting the area of the nucleation control region sufficiently small as compared with the area of the growth control region. That is, the amount of the organic solution stored in the nucleation control region is sufficiently small as compared with the amount of the organic solution stored in the growth control region and, therefore, the vaporization speed of the solvent from the organic solution stored in the nucleation control region is sufficiently large as compared with the vaporization speed of the solvent of the organic solution stored in the growth control region. Consequently, it is possible that in the nucleation control region, the concentration increases because of fast vaporization of the solvent and, thereby, the state of the organic solution comes into the unstable region, and meanwhile, at the same time, in the growth control region, an increase in concentration is slow because of slow vaporization of the solvent and, thereby, the state of the organic solution comes into the metastable region. In this case, nucleation from the organic solution can be effected only in the nucleation control region in which the state of the organic solution is in the unstable region. At this time, in the nucleation control region, a large number of crystal nuclei of the organic semiconductor are formed in the organic solution, although finally, only one crystal nucleus grows sufficiently largely. The thus grown crystal blocks a coupling portion to the growth control region. Then, a crystal grows on the growth control region from the resulting crystal and, thereby, a single domain crystal (single crystal) grows. In this regard, the degree of supersaturation of the organic solution stored on the organic semiconductor becomes a maximum at the surface of the organic solution and, therefore, the crystal grows in a lateral direction while floating in the organic solution. In this manner, finally, an organic semiconductor single crystal thin film grows on the insulating film sunk on the one principal surface of the base substance in advance. In this case, the organic semiconductor single crystal thin film grows on the insulating film without being exposed to the air, so that a good organic semiconductor single crystal thin film/insulating film interface can be obtained. In the case where the solvent in the organic solution is vaporized, for example, the organic solution is kept at a constant temperature, for example, a constant temperature of 15° C. or higher and 20° C. or lower, although not necessarily limit to this.

Examples of methods for sinking the organic insulator in the organic solution on the one principal surface of the base substance prior to the organic semiconductor include a method in which the specific gravity of the organic insulator is made larger than the specific gravity of the organic semiconductor. Alternatively, as for the organic solution, an organic solution made from a first organic solution, in which the organic semiconductor is dissolved in a first solvent, and a second organic solution, in which the organic insulator is dissolved into a second solvent, is used, wherein the specific gravity of the first solvent is smaller than the specific gravity of the second solvent. The method for sinking the organic insulator in the organic solution on the one principal surface of the base substance is not limited to this. For example, the organic insulator may be sunk taking advantage of spinodal decomposition (spinodal decomposition) from the organic solution. That is, the organic solution is a two-component mixed system containing the organic semiconductor and the organic insulator and two-phase separation is effected by this organic solution being quenched from a high temperature and brought into an unstable state and, as a result, the organic insulator can be sunk.

The organic semiconductor element may basically be of any type insofar as the organic semiconductor element has a structure in which an organic semiconductor single crystal thin film is disposed on an insulating film, and is typically an organic transistor having a configuration of an insulated gate field-effect transistor (in particular, thin film transistor (TFT)). In this organic transistor, a gate electrode is formed on the one principal surface of the base substance, the above-described insulating film is formed as a gate insulating film on this gate electrode, and the above-described organic semiconductor single crystal thin film is grown as a channel layer on this insulating film. Here, in general, the crystal orientation of the organic semiconductor single crystal thin film can be further aligned by reducing the width of the nucleation control region. Therefore, regarding this organic transistor, favorably, the channel length direction (direction bonding a source electrode and a drain electrode) is set to be the direction in which the carrier mobility of the organic semiconductor single crystal thin film is high. Consequently, a high-carrier mobility organic transistor or organic transistor array can be realized.

As for the organic semiconductor, various known materials in the related art can be used. For example, the following materials can be used.

(1) Polypyrrole and derivatives thereof
(2) Polythiophene and derivatives thereof
(3) Isothianaphthenes, e.g., polyisothianaphthene
(4) Thienylenevinylenes, e.g., polythienylenevinylene
(5) Poly(p-phenylenevinylene)s, e.g., poly(p-phenylenevinylene)
(6) Polyaniline and derivatives thereof

### (7) Polyacetylenes

### (8) Polydiacetylenes

### (9) Polyazulenes

### (10) Polypyrenes

### (11) Polycarbazoles

### (12) Polyselenophenes

### (13) Polyfurans

### (14) Poly(p-phenylene)s

### (15) Polyindoles

### (16) Polypyridazines

(17) Acenes, e.g., naphthacene, pentacene, hexacene, heptacene, dibenzopentacene, tetrabenzopentacene, pyrene, dibenzopyrene, chrysene, perylene, coronene, terylene, ovalene, quaterrylene, and circumanthracene
(18) Derivatives of acenes in which a part of carbon is substituted with atoms, e.g., nitrogen, sulfur, and oxygen, or functional groups, e.g., a carbonyl group, for example, triphenodioxazine, triphenodiazine, and hexacene-6,15-quinone
(19) Polymer materials and polycyclic condensates, e.g., polyvinylcarbazole, polyphenylene sulfide, and polyvinylene sulfide
(20) Oligomers having the same repeating unit as those in the polymer materials of the item (19)
(21) Metal phthalocyanines
(22) Tetrathiafulvalene and derivatives thereof
(23) Tetrathiapentalene and derivatives thereof
(24) Naphthalene-1,4,5,8-tetracarboxylic acid diimide, N,N′-bis(4-trifluoromethylbenzyl)naphthalene-1,4,5,8-tetracarboxylic acid diimide, N,N′-bis(1H,1H-perfluorooctyl), N,N′-bis(1H,1H-perfluorobutyl), and N,N′-dioctylnaphthalene-1,4,5,8-tetracarboxylic acid diimide derivatives
(25) Naphthalene tetracarboxylic acid diimides, e.g., naphthalene-2,3,6,7-tetracarboxylic acid diimide
(26) Condensed ring tetracarboxylic acid diimides typified by anthracene tetracarboxylic acid diimides, e.g., anthracene-2,3,6,7-tetracarboxylic acid diimide
(27) Coloring agents, e.g., merocyanine dyes and hemicyanine dyes

As for the organic semiconductor, favorably, aromatic compounds and derivatives thereof are used. The aromatic compounds are classified into benzene based aromatic compounds, heteroaromatic compounds, and non-benzene based benzene based aromatic compounds. The benzene based aromatic compounds include condensed ring aromatic compounds, for example, benzo condensed ring compounds. Examples of heteroaromatic compounds include furan, thiophene, pyrrole, and imidazole. Examples of non-benzene based aromatic compounds include annulene, azulene, a cyclopentadienyl anion, a cyclroheptatrienyl cation (tropylium ion), tropone, metallocene, and acepleiadylene. Among these aromatic compounds, favorably, condensed ring compounds are used. Examples of condensed ring compounds include acenes (naphthalene, anthracene, tetracene, pentacene, and the like), phenanthrene, chrysene, triphenylene, tetraphene, pyrene, picene, pentaphene, perylene, hericene, and coronene, although not limited to them. In one typical example, as for these aromatic compounds, dioxaanthanthrene based compounds, e.g., 6,12-dioxaanthanthrene (so-called peri-xanthenoxanthene, 6,12-dioxaanthanthrene, and may be abbreviated as “PXX”), are used (refer to PTL 1 and NPL 2).

The electronic apparatuses may be various electronic apparatuses by using at least one organic semiconductor element and include both the portable type apparatuses and the stationary type apparatuses irrespective of function and use. Concrete examples of the electronic apparatuses include displays, e.g., liquid crystal displays and organic electroluminescence displays, cellular phones, mobile apparatuses, personal computers, game apparatuses, car-mounted apparatuses, home electric appliances, and industrial products.

### Advantageous Effects of Invention

According to the present disclosure, good organic semiconductor single crystal thin film/insulating film interface can be obtained and, thereby, a high-performance organic semiconductor element, e.g., an organic transistor having sufficiently high carrier mobility, can be realized. Then, a high-performance electric apparatus can be realized by using this high-performance organic semiconductor element.

### BRIEF DESCRIPTION OF DRAWINGS

FIG. 1 is a sectional view showing an organic transistor according to a first embodiment.

FIG. 2 is a schematic diagram showing the solubility-supersolubility diagram regarding an organic solution used for growing an organic semiconductor single crystal thin film in the first embodiment.

FIG. 3 is a plan view showing a substrate used in a method for growing the organic semiconductor single crystal thin film used in the first embodiment.

FIG. 4A is a schematic diagram for explaining the method for growing the organic semiconductor single crystal thin film used in the first embodiment.

FIG. 4B is a schematic diagram for explaining the method for growing the organic semiconductor single crystal thin film used in the first embodiment.

FIG. 4C is a schematic diagram for explaining the method for growing the organic semiconductor single crystal thin film used in the first embodiment.

FIG. 5A is a schematic diagram showing a model of a simulation made to examine the growth mechanism of the method for growing the organic semiconductor single crystal thin film used in the first embodiment.

FIG. 5B is a schematic diagram showing a model of a simulation made to examine the growth mechanism of the method for growing the organic semiconductor single crystal thin film used in the first embodiment.

FIG. 6A is a schematic diagram showing the result of the simulation made to examine the growth mechanism of the method for growing the organic semiconductor single crystal thin film used in the first embodiment.

FIG. 6B is a schematic diagram showing the result of the simulation made to examine the growth mechanism of the method for growing the organic semiconductor single crystal thin film used in the first embodiment.

FIG. 7A is a photograph substituted for a drawing, showing a polarization optical micrograph of a matrix array of a C₂ Ph-PXX thin film grown by the method for growing the organic semiconductor single crystal thin film used in the first embodiment and the C₂ Ph-PXX thin film having a typical shape.

FIG. 7B is a photograph substituted for a drawing, showing a polarization optical micrograph of a matrix array of a C₂ Ph-PXX thin film grown by the method for growing the organic semiconductor single crystal thin film used in the first embodiment and the C₂ Ph-PXX thin film having a typical shape.

FIG. 7C is a photograph substituted for a drawing, showing a polarization optical micrograph of a matrix array of a C₂ Ph-PXX thin film grown by the method for growing the organic semiconductor single crystal thin film used in the first embodiment and the C₂ Ph-PXX thin film having a typical shape.

FIG. 8A is a photograph substituted for a drawing, showing a selected area electron diffraction pattern of a C₂ Ph-PXX thin film grown by the method for growing the organic semiconductor single crystal thin film used in the first embodiment and a schematic diagram showing a facet of the C₂ Ph-PXX thin film.

FIG. 8B is a photograph substituted for a drawing, showing a selected area electron diffraction pattern of a C₂ Ph-PXX thin film grown by the method for growing the organic semiconductor single crystal thin film used in the first embodiment and a schematic diagram showing a facet of the C₂ Ph-PXX thin film.

FIG. 8C is a photograph substituted for a drawing, showing a selected area electron diffraction pattern of a C₂ Ph-PXX thin film grown by the method for growing the organic semiconductor single crystal thin film used in the first embodiment and a schematic diagram showing a facet of the C₂ Ph-PXX thin film.

FIG. 9 is a schematic diagram showing the distribution of the rotation angle of a C₂ Ph-PXX thin film grown in the shape of a matrix array by the method for growing the organic semiconductor single crystal thin film used in the first embodiment, where the width of a comb tooth portion of a comb-shaped pattern is specified to be 5 μm.

FIG. 10 is a schematic diagram showing the distribution of the rotation angle of a C₂ Ph-PXX thin film grown in the shape of a matrix array by the method for growing the organic semiconductor single crystal thin film used in the first embodiment, where the width of a comb tooth portion of a comb-shaped pattern is specified to be 10 μm.

FIG. 11A is a schematic diagram for explaining the growth mechanism of the method for growing the organic semiconductor single crystal thin film used in the first embodiment.

FIG. 11B is a schematic diagram for explaining the growth mechanism of the method for growing the organic semiconductor single crystal thin film used in the first embodiment.

FIG. 12A is a schematic diagram for explaining the growth mechanism of the method for growing the organic semiconductor single crystal thin film used in the first embodiment.

FIG. 12B is a schematic diagram for explaining the growth mechanism of the method for growing the organic semiconductor single crystal thin film used in the first embodiment.

FIG. 13 is a schematic diagram for explaining the growth mechanism of the method for growing the organic semiconductor single crystal thin film used in the first embodiment.

FIG. 14 is a schematic diagram showing a film-forming apparatus used for growing the organic semiconductor single crystal thin film in the first embodiment.

FIG. 15A is a sectional view for explaining a method for manufacturing an organic transistor according to the first embodiment.

FIG. 15B is a sectional view for explaining a method for manufacturing an organic transistor according to the first embodiment.

FIG. 15C is a sectional view for explaining a method for manufacturing an organic transistor according to the first embodiment.

FIG. 16 is a schematic diagram showing a film-forming apparatus used for growing the organic semiconductor single crystal thin film in the first embodiment.

FIG. 17A is a plan view and a sectional view for explaining a concrete example in which an organic semiconductor single crystal thin film is grown in a lateral direction on a fine-line pattern made from Au.

FIG. 17B is a plan view and a sectional view for explaining a concrete example in which an organic semiconductor single crystal thin film is grown in a lateral direction on a fine-line pattern made from Au.

FIG. 18A is a photograph substituted for a drawing, showing a cross-sectional transmission electron micrograph of a sample in which an organic semiconductor single crystal thin film is grown in a lateral direction on a fine-line pattern made from Au.

FIG. 18B is a photograph substituted for a drawing, showing a cross-sectional transmission electron micrograph of a sample in which an organic semiconductor single crystal thin film is grown in a lateral direction on a fine-line pattern made from Au.

FIG. 19A is a sectional view for explaining a method for manufacturing an organic transistor according to a second embodiment.

FIG. 19B is a sectional view for explaining a method for manufacturing an organic transistor according to the second embodiment.

FIG. 19C is a sectional view for explaining a method for manufacturing an organic transistor according to the second embodiment.

FIG. 19D is a sectional view for explaining a method for manufacturing an organic transistor according to the second embodiment.

### DESCRIPTION OF EMBODIMENTS

The embodiments to execute the invention (hereafter referred to as “embodiments”) will be described below. The explanations will be made in the following order.

1. First embodiment (organic transistor and method for manufacturing the same)
2. Second embodiment (method for manufacturing organic transistor)
3. Third embodiment (method for manufacturing organic transistor)

### 1. First Embodiment

### Organic Transistor

FIG. 1 shows an organic transistor according to the first embodiment.

As shown in FIG. 1, in this organic transistor, a gate electrode 12 is disposed on a substrate 11. An insulating film 13 is filled in a portion outside this gate electrode 12. The upper surface of the insulating film 13 is flush with the upper surface of the gate electrode 12. A gate insulating film 14 is disposed in such a way as to cover these gate electrode 12 and insulating film 13. An organic semiconductor single crystal thin film 15 serving as a cannel layer is disposed on this gate insulating film 14. A source electrode 16 and a drain electrode 17 are disposed apart from each other on this organic semiconductor single crystal thin film 15. These gate electrode 12, organic semiconductor single crystal thin film 15, source electrode 16, and drain electrode 17 constitute a top contact-bottom gate type organic transistor having the configuration of an insulated gate field-effect transistor.

Regarding this organic transistor, favorably, the channel length direction (direction bonding the source electrode 16 and the drain electrode 17) is set to be the direction in which the carrier mobility of the organic semiconductor single crystal thin film 15 is high.

The thickness of the organic semiconductor single crystal thin film 15 is selected appropriately in accordance with, for example, the characteristics required for this organic transistor. As for the organic transistor constituting the organic semiconductor single crystal thin film 15, the semiconductors mentioned above can be used and are selected as necessary. Among them, some concrete examples of peri-xanthenoxanthene (PXX) based compounds are as described below.

[chemical structure]

(where R represents an alkyl group irrespective of straight-chain or branched)

[chemical structure]

(where R represents an alkyl group irrespective of straight-chain or branched)

[chemical structure]

(where R represents an alkyl group irrespective of straight-chain or branched)

[chemical structure]

(where R represents an alkyl group and the number of R is 2 to 5)

[chemical structure]

(where R represents an alkyl group and the number of R is 1 to 5)

[chemical structure]

(where R represents an alkyl group and the number of R is 1 to 5)

[chemical structure]

(where A₁ and A₂ are represented by Formula (8))

[chemical structure]

(where R represents an alkyl group or other substituent and the number of R is 1 to 5)

[chemical structure]

[chemical structure]

The insulating film 13 and the gate insulating film 14 are made from an organic insulator. Examples of organic insulators include polyvinylphenols, polymethyl methacrylates, polyimides, fluororesins, PVP-RSiCl₃, DAP, isoDAP, poly(α-methylstyrene)s, and cycloolefin-copolymers. The thickness of the gate insulating film 14 is selected appropriately in accordance with, for example, the characteristics required for this organic transistor.

The material for the substrate 11 is selected, as necessary, from various known materials in the related art and may be a transparent material or an opaque material with respect to the visible light. Furthermore, the substrate 11 may be electrically conductive or nonconductive. Moreover, the substrate 11 may be flexible (pliable) or may not be flexible. Concretely, examples of the materials for the substrate 11 include various types of plastic (organic polymer), e.g., polymethylmethacrylate (polymethacrylic acid methyl, PMMA), polyvinyl alcohol (PVA), polyvinylphenol (PVP), polyethersulfone (PES), polyimide, polycarbonate, polyethylene terephthalate (PET), and polyethylene naphthalate (PEN), mica, various glass substrates, quartz substrates, silicon substrates, various alloys, e.g., stainless steels, and various metals. The substrate 11 can be made flexible by using plastic as the material for the substrate 11 and, by extension, a flexible organic transistor can be obtained. As for the plastic substrate, for example, substrates made of polyimide, polycarbonate, polyethylene terephthalate, polyethylene naphthalate, polyethersulfone, and the like are used.

Examples of materials constituting the gate electrode 12, the source electrode 16, and the drain electrode 17 include various electrically conductive materials, for example, metals, e.g., platinum (Pt), gold (Au), palladium (Pd), chromium (Cr), molybdenum (Mo), nickel (Ni), aluminum (Al), silver (Ag), tantalum (Ta), tungsten (W), copper (Cu), titanium (Ti), indium (In), and tin (Sn), or alloys containing these metal elements, electrically conductive particles made from these metals, electrically conductive particles of alloys containing these metals, and polysilicon containing impurities. Examples of materials constituting the gate electrode 12, the source electrode 16, and the drain electrode 17 also include various organic electrically conductive materials (electrically conductive polymers), e.g., poly(3,4-ethylenedioxythiophene)/polystyrenesulfonic acid [PEDOT/PSS] and tetrathiafulvalene-7,7,8,8-tetracyanoquinodimethane (TTF-TCNQ). The gate electrode 12, the source electrode 16, and the drain electrode 17 may also have a laminated structure of at least two types of layers made from these materials. The width of the gate electrode 12 in the channel length direction (gate length) and the distance between the source electrode 16 and the drain electrode 17 (channel length) are selected appropriately in accordance with, for example, the characteristics required for this organic transistor.

### [Method for Manufacturing Organic Transistor]

Before the method for manufacturing this organic transistor is explained, a new method for growing an organic semiconductor single crystal thin film will be described, the method having been developed by the present inventors originally.

FIG. 2 shows the solubility-supersolubility diagram (solubility-supersolubility diagram) regarding an organic solution (a solution in which an organic semiconductor is dissolved in a solvent) used for growing this organic semiconductor single crystal thin film. As shown in FIG. 2, along with a decrease in temperature and/or an increase in concentration, the state of the organic solution changes from an unsaturated region (stable region) above a solubility curve to a supersaturated region under the solubility curve. In the stable region, spontaneous crystallization does not occur. The crystallization can proceed in the supersaturated region. The supersaturated region can be divided into two regions. One region is a metastable region between the solubility curve and a supersolubility curve. In this metastable region, only crystal growth occurs and nucleation dos not occur. The other region is an unstable region under the supersolubility curve. In this unstable region, spontaneous crystallization can occur.

One example of the method for growing the organic semiconductor single crystal thin film will be described with reference to FIG. 2. As shown in FIG. 3, a comb-shaped pattern P having a lyophilic (lyophilic) surface S₁ with respect to the organic solution is formed on the substrate, although not shown in the drawing. This comb-shaped pattern P having a lyophilic surface S₁ is a region which is wetted by the organic solution easily and which has a property to fix the organic solution. The surface of the substrate other than this comb-shaped pattern P is specified to be a lyophobic (lyophobic) surface S₂ with respect to the organic solution. The region having this lyophobic surface S₂ is a region which is not wetted by the organic solution easily and has a property to repel the organic solution. The comb-shaped pattern P is formed from a rectangular back portion P₁ and a plurality of rectangular comb tooth portions P₂ which are disposed along one long side of this back portion P₁ at regular intervals and which are protruded in the direction perpendicular to this long side. The area of the back portion P₁ is sufficiently large relative to the area of each comb tooth portion P₂.

Here, when a droplet of the organic solution is placed on this comb-shaped pattern P, this droplet is held on the lyophilic surface S₁ of this comb-shaped pattern P and does not move to the lyophobic surface S₂ outside this comb-shaped pattern P. The shift of the state of droplet of this organic solution to the supersaturated region can be realized by increasing the concentration of the organic solution through the use of vaporization of the solvent. In FIG. 2, a broken line ABC shows an example of a method for performing the above-described operation at a constant temperature of T_{g}. Regarding the back portion P₁ which has a large area and which can store large amounts of organic solution, rapid vaporization of the solvent is suppressed. This back portion P₁ region is used as a growth control region (growth control region, GCR). Meanwhile, the comb tooth portions P₂ region is used as a nucleation control region (nucleation control region, NCR). The area of the comb tooth portion P₂ is sufficiently small as compared with the area of the back portion P₁. Therefore, the amount of the organic solution on each comb tooth portion P₂ is sufficiently small as compared with the amount of the organic solution on the back portion P₁ and the vaporization speed of the solvent from each comb tooth portion P₂ that is, the nucleation control region, is significantly large as compared with the vaporization speed of the solvent from the back portion P₁, that is, the growth control region. The degree of local supersaturation of droplet of the organic solution can be controlled with high accuracy by taking advantage of the fact that there is a large difference in vaporization speed of the solvent between the organic solution in the portion on the back portion P₁, that is, the growth control region, and the organic solution in the portion on each comb tooth portion P₂, that is, the nucleation control region, as described above.

A growth model of an organic semiconductor single crystal thin film on the basis of solution growth from the organic solution will be described by using FIG. 4A, FIG. 4B, and FIG. 4C. FIG. 4A shows one comb tooth portion P₂ and a part of the back portion P₁ in the comb-shaped pattern P. A droplet of the organic solution is held on this back portion P₁ and the comb tooth portion P₂. The organic solution in this state is in the stable state A shown in FIG. 2. When vaporization of the organic solution is started, the vaporization speed of the solvent in the organic solution of the portion on the comb tooth portion P₂ is large as compared with that of the organic solution of the portion on the back portion P₁ and, therefore, an increase in concentration of the organic solution is fast. Consequently, a state is realized, in which the organic solution of the portion on the back portion P₁ is in the metastable state B shown in FIG. 2, while the organic solution of the portion on the comb tooth portion P₂ is in the unstable state C shown in FIG. 2. That is, although the back portion P₁ and the comb tooth portion P₂ are adjacent to each other, the state of the organic solution can be set to be the metastable state B in the back portion P₁ and the unstable state C in the comb tooth portion P₂, which are different from each other, at the same time. In the comb tooth portion P₂ in which the organic solution is in the unstable state C, that is, the nucleation control region, spontaneous crystallization can occur and crystal nuclei may be formed at a plurality of places in the region on the comb tooth portion P₂. However, finally, as shown in FIG. 4B, only one crystal C grows to a size sufficient for completely blocking the comb tooth portion P₂. Then, as shown in FIG. 4C, an organic semiconductor single crystal thin film F grows from the stable crystal C blocking this comb tooth portion P₂ to the back portion P₁ in which the organic solution is in the metastable state B, that is, the growth control region. As is clear from that described above, according to this method, the organic semiconductor single crystal thin film F can be grown on the back portion P₁ while the comb tooth portion P₂ serves as a starting point. That is, it is clear that the position, at which the organic semiconductor single crystal thin film F is grown, can be controlled with high accuracy.

Regarding a rectangular region surrounded by a broken line shown in FIG. 3, in order to examine the behavior of vaporization of the solvent in the organic solution, computational fluid dynamic simulation was performed with respect to the shape of droplet of the organic solution and the vaporization speed. In order to simplify the calculation, the shape of droplet of the solvent was calculated by using computational fluid dynamic (CFD) software FLOW-3D^{R} in consideration of the surface tension and the contact angle of the solvent. The surface tension of the solvent was specified to be 35.9 N/m. The contact angle θ of the solvent was determined as 6 degrees with respect to a lyophilic surface and 63 degrees with respect to a lyophobic surface through experiments. Furthermore, the viscosity of the solvent was specified to be μ=0.01 Pa·s and the density was specified to be ρ=1.030 kg/m³. FIG. 5A and FIG. 5B schematically show an initial and final shapes, respectively, of the droplet of the solvent on the comb-shaped pattern P. The size of each portion is as shown in FIG. 5A and FIG. 5B. As shown in FIG. 5A, a droplet L of the solvent in the early stage is present on the comb-shaped pattern P while having a uniform thickness (10 μm in this example). As shown in FIG. 5B, finally, the droplet L of the solvent on the back portion P₁ takes on the shape in which a central portion is protruded because of surface tension (hogback (hogback) shape). The thickness of the droplet L is 16.5 μm on the back portion P₁, that is, growth control region, and is 2.7 μm in the comb tooth portion P₂, that is, nucleation control region. Therefore, it is clear that the amount of the solvent on the comb tooth portion P₂, that is, the nucleation control region, is significantly small as compared with the amount of the solvent on the back portion P₁, that is, growth control region. As a result, the vaporization speed of the solvent on the comb tooth portion P₂, that is, the nucleation control region, is significantly large as compared with the vaporization speed of the solvent on the back portion P₁, that is, the growth control region.

The vaporization speed of the solvent can be represented by the following differential equation.

dw/dt=−C(P_{sat.}−P)

Here, w, C, P_{sat.}, P, and t represent the mass of the molecule of the solvent, a constant coefficient, a saturated vapor pressure of the solvent, and the vapor pressures of the solvent and t, respectively. FIG. 6A and FIG. 6B show the calculation results of the vapor density of the solvent on the comb tooth portion P₂ at some time before the vaporization of the solvent is finished. In this regard, temperature was specified to be 20° C. FIG. 6A and FIG. 6B shows the distribution of the vapor density of the solvent, when viewed from above the comb-shaped pattern P, and the distribution of the vapor density of the solvent in a cross-section of the comb-shaped pattern P, respectively. FIG. 6A and FIG. 6B also show constant-vapor density lines. The interval of the constant-vapor density line is reduced as the inclination increases. The vapor pressure is nearly equal to the saturated vapor pressure at the surface of the solvent, so that the vaporization speed of the solvent in the comb tooth portion P₂, that is, the nucleation control region, is always large as compared with the vaporization speed of the solvent in the back portion P₁, that is, the growth control region. This is because the comb tooth portion P₂ is not surrounded by the solvent and, therefore, the diffusion speed of the solvent molecule vaporized in the comb tooth portion P₂ is larger than that in the back portion P₁.

According to the above-described simulation results, it is supported that the shift from the stable state A to the unstable state C shown in FIG. 2 occurs in the comb tooth portion P₂ at first and, as a result, spontaneous crystallization occurs. Furthermore, it is clear that a large difference in vaporization of the solvent occurs between the back portion P₁, that is, the growth control region, and the comb tooth portion P₂, that is, the nucleation control region, because of not only the amount of the solvent, but also the vaporization speed.

The results of examination of the growth mechanism by performing actual growth of an organic semiconductor single crystal thin film will be described.

As for a substrate to grow the organic semiconductor single crystal thin film, a 4-inch silicon substrate doped with high-concentration impurities and provided with a SiO₂ film on the surface was used. The surface of this silicon substrate was cleaned and, thereafter, a comb-shaped pattern P was formed thereon in the following manner. That is, a lyophobic surface S₂ was formed by forming an amorphous fluororesin film (CYTOP produced by ASAHI GLASS CO., LTD.) in the portion other than the portion to be provided with the comb-shaped pattern P of the surface of the silicon substrate by a lift-off method. The surface of the portion inside this lyophobic surface S₂ is the lyophilic surface S₁ and this portion serves as the comb-shaped pattern P. The size of the back portion P₁ of the comb-shaped pattern P was 200 μm×6.5 mm, and 12 units of this comb-shaped pattern P were formed parallel to each other while being 300 μm apart from each other. The width of the comb tooth portion P₂ of the comb-shaped pattern P was specified to be 5 μm or 10 μm, the length was specified to be 40 μm, and the interval of the comb tooth portions P₂ was specified to be 200 μm. The number of the comb tooth portions P₂ per comb-shaped pattern P was specified to be 32. That is, the comb tooth portions P₂ were formed into the 12×32 matrix array. As for the organic semiconductor single crystal thin film, a C₂ Ph-PXX thin film was selected. This is because C₂ Ph-PXX is dissolved into a solvent at room temperature sufficiently and has excellent stability in the air. A C₂ Ph-PXX powder was dissolved into tetralin at room temperature, so as to prepare an organic solution having a C₂ Ph-PXX concentration of 0.4 percent by weight. The resulting organic solution was dropped to the above-described silicon substrate in the air and, thereafter, the resulting silicon substrate was placed on a holder disposed in the inside of a film-forming apparatus descried later, so as to grow C₂ Ph-PXX thin film on this silicon substrate. The temperature of the holder was kept at 17° C. That is, the growth temperature was 17° C. When this silicon substrate was introduced into the inside of the film-forming apparatus, a nitrogen (N₂) gas was passed at a flow rate of 0.3 L/min from a gas introduction pipe kept at about 60° C. After growth was finished, the silicon substrate was dried in a vacuum oven at 80° C. for 8 hours, so as to remove completely the solvent remaining on the silicon substrate surface.

FIG. 7A shows a polarization optical micrograph of the C₂ Ph-PXX thin film grown as described above. In this regard, the width of the comb tooth portion P₂ was specified to be 5 μm. FIG. 7B and FIG. 7C show polarization optical micrographs showing the typical shapes of these C₂ Ph-PXX thin films. As is clear from FIG. 7A, FIG. 7B, and FIG. 7C, the growth occurs in the same manner as described with reference to FIG. 2, FIG. 3, FIG. 4A, FIG. 4B, and FIG. 4C. That is, every C₂ Ph-PXX thin film is grown from the intersection portion of the comb tooth portion P₂ and the back portion P₁ toward the back portion P₁. This indicates that the growth position of the C₂ Ph-PXX thin film can be controlled accurately. The sizes of these C₂ Ph-PXX thin films were about 100×100 μm². Furthermore, the thicknesses of these C₂ Ph-PXX thin films were about 0.2 μm. The contrasts in the individual C₂ Ph-PXX thin films are on the basis of differences in thickness depending on places. All C₂ Ph-PXX thin films have the same facet angles of 82 degrees or 98 degrees. This indicates that facet growth is effected. This result indicates that all C₂ Ph-PXX thin films are single domain crystals, put another way, single crystal thin films. In addition, the yield defined as the value determined by dividing the number of these C₂ Ph-PXX thin films by the number of the comb tooth portions P₂ is 98.2% of the 12×32 matrix array. This indicates that this method has the potential for becoming a large area process.

In order to examine the structure of the above-described C₂ Ph-PXX thin film in detail, electron microscope observation was performed with a transmission electron microscope (TEM) (JEOL JEM-4000FXS) under the condition of an accelerating voltage of 400 kV and low dose. FIG. 8A shows a selected area electron diffraction pattern of a C₂ Ph-PXX thin film on the basis of plane TEM observation. As is clear from FIG. 8A, each diffraction spot is observed clearly, and this indicates that the C₂ Ph-PXX thin film is a single crystal. The lattice constants in the plane (a axis and b axis) of 1.1 nm and 1.3 nm, respectively, are obtained from the period of diffraction pattern. The angle formed by the two directions of the a axis and the b axis is 90.5 degrees. It is clear from the cross-sectional TEM photograph that the lattice constant in the c axis direction is 2.2 nm, and this agrees with the length of the C₂ Ph-PXX molecule completely. In this regard, the angle formed by the two directions of the a axis and the b axis is about 90 degrees and, therefore, the crystal structure of the C₂ Ph-PXX thin film was assumed to be an orthorhombic system. In FIG. 8B, characteristic facet angles of 82 degrees and 98 degrees are observed. As shown in FIG. 8C, in a real space, the rectangle surrounded by {110} facets has characteristic vertexes having angles of 82 degrees and 98 degrees at both ends of diagonals. Therefore, in FIG. 8C, facet growth is observed clearly, so that it can be concluded that all C₂ Ph-PXX thin films are single crystals.

In order to examine the crystal orientation of the C₂ Ph-PXX thin film, rotation angles of all the C₂ Ph-PXX thin films shown in FIG. 7A were examined. It is defined that the shape of the C₂ Ph-PXX thin film, in which the (−110) direction is parallel to the longitudinal direction of the comb tooth portion P₂, that is, the nucleation control region, corresponds to the rotation angle of 0 degrees. The right-handed and the left-handed rotations are indicated by positive and negative rotation angles, respectively. FIG. 9 shows a histogram of the rotation angle of the C₂ Ph-PXX thin film, where the width of the comb tooth portion P₂ is 5 μm. Diagrams inserted in the upper portion of FIG. 9 show the shapes of the crystals of the C₂ Ph-PXX thin films corresponding to the individual rotation angles. It is clearly observed from FIG. 9 that the C₂ Ph-PXX thin films have rotation angles of about −48 degrees and 0 degrees. Among all C₂ Ph-PXX thin films, the proportion of thin films having a rotation angle within about −48 degrees±10 degrees and the proportion of thin films having a rotation angle within about 0 degrees±10 degrees were estimated to be 29.1% and 13.1%, respectively. Therefore, the shape having a rotation angle of about −48 degrees was predominant. This shape corresponds to the shape of the C₂ Ph-PXX thin film shown in FIG. 7B. FIG. 10 shows a histogram of the C₂ Ph-PXX thin film, where the width of the comb tooth portion P₂ is 10 μm. As shown in FIG. 10, a specific rotation angle is not present in this case. This result indicates that the crystal orientation of the C₂ Ph-PXX thin film depends on the width of the comb tooth portion P₂. As the width of the comb tooth portion P₂ decreases, the C₂ Ph-PXX thin films having the shape shown in FIG. 7B increase.

Consequently, the following important results have been obtained. First, a single domain, that is, a single crystal C₂ Ph-PXX thin film can be grown. Second, the crystal orientation of the C₂ Ph-PXX thin film depends on the width of the comb tooth portion P₂, and when the width of the comb tooth portion P₂ decreases, there is a tendency of the crystal orientation to align. It is believed that these results have a close relationship to a phenomenon in the region of the comb tooth portion P₂. FIG. 11A and FIG. 11B show a crystallization mechanism in the region of the comb tooth portion P₂ in an early stage of vaporization of the solvent. Meanwhile, FIG. 12A and FIG. 12B show a crystallization mechanism in the region of the comb tooth portion P₂ in a final stage of vaporization of the solvent. Here, FIG. 11A and FIG. 12A show sectional views, and FIG. 11B and FIG. 12B show top views. As shown in FIG. 11A and FIG. 11B, in the early stage of vaporization of the solvent, a plurality of crystal nuclei N are formed on the surface of the droplet L of the organic solution in the region of the comb tooth portion P₂. In the final stage of vaporization of the solvent, as shown in FIG. 12A and FIG. 12B, finally only one crystal nucleus N is sufficiently largely grown and becomes a stable crystal C, so as to block the comb tooth portion P₂. The reason therefor is believed to be that the growth speed has anisotropy, as shown in FIG. 13 (the length of an arrow indicated by a broken line in FIG. 13 represents a growth speed). That is, in the early stage of vaporization, the energy to form nonuniform nuclei is lower than the energy to form uniform nuclei and, thereby, a large number of crystal nuclei N are formed nonuniformly at the interface between the droplet L and the lyophobic surface S₂. The facet of the crystal is a stable surface, so that the crystal nucleus N comes into contact with the interface between the droplet L and the lyophobic surface S₂, so as to form the {110} face. When the crystal nucleus N does not touch the interface between the droplet L and the lyophobic surface S₂ and is moved to the uppermost portion of the droplet L, the crystal nuclei N are arranged in such a way that the surface tension becomes a maximum. As the width of the comb tooth portion P₂ decreases, the radius of curvature of the droplet L decreases. Therefore, as the width of the comb tooth portion P₂ decreases, it is significantly advantageous that the shape of the crystal nucleus N becomes slender. There are two cases, a case where the crystal nucleus N does not touch immediately and a case where the crystal nucleus N does not touch slowly. In the case of not touch immediately, as shown in FIG. 11B (1), the crystal nucleus N grows isotropically and, as a result, a shape having a rotation angle of 48 degrees is formed. However, on the other hand, in the case of not touch slowly, as shown in FIG. 11B (2), the growing <110> or <1-10> facet face is not in contact with the interface between the droplet L and the lyophobic surface S₂, so that the crystal nucleus N grows anisotropically. Therefore, the shape having a rotation angle of about 0 degrees is very advantageous. In this regard, it is considered that the <110> or <1-10> facet face comes into contact with the interface between the droplet L and the lyophobic surface S₂. In this case, it is believed that the shape having a rotation angle of about ±90 degrees is obtained. The reason for this is believed that the bonding force between the interface between the droplet L and the lyophobic surface S₂ and the {110} face is larger than the bonding force between the interface between the droplet L and the lyophobic surface S₂ and the {1-10} face.

### [Film-Forming Apparatus]

An example of the film-forming apparatus used for growing the above-described organic semiconductor single crystal thin film will be described.

FIG. 14 shows a film-forming apparatus used for growing the organic semiconductor single crystal thin film 15. As shown in FIG. 14, this film-forming apparatus includes a chamber 21 and a solvent tank 23 connected to this chamber 21 with a connection pipe 22 therebetween. The chamber 21 can be sealed while being connected to the solvent tank 23. The chamber 21 is provided with an exhaust pipe 24. In the chamber 21, a holder 25 is disposed in such a way that the temperature can be controlled, and a base substance (not shown in the drawing) subjected to film formation is placed on this holder 25.

In the solvent tank 23, an auxiliary solvent 26 of the same type as the solvent in the organic solution used for growing the organic semiconductor single crystal thin film 15 is accumulated. The temperature of this auxiliary solvent 26 can be adjusted by a heating device, e.g., an oil bath, although not shown in the drawing. A gas can be introduced into the auxiliary solvent 26 through a gas introduction pipe 27 introduced from the outside to the inside of the solvent tank 23. The solvent tank 23 can supply a vapor containing the vapor of the auxiliary solvent 26 to the chamber 21 through the connection pipe 22. Consequently, the surrounding environment of the organic solution, that is, the pressure (vapor pressure) P in the inside of the chamber 21, is controlled in accordance with the temperature of the auxiliary solvent 26. In this regard, the vapor supplied to the chamber 21 can be exhausted to the outside through the exhaust pipe 24, as necessary.

A method for manufacturing this organic transistor will be described assuming those described above.

Initially, as shown in FIG. 15A, a gate electrode 12 is formed on a substrate 11 by a known method in the related art.

Subsequently, an insulating film 13, e.g., a SiO₂ film, is formed all over the substrate 11 in such a way as to cover the gate electrode 12. Thereafter, the resulting insulating film 13 is etched back by, for example, a reactive ion etching (RIE) method until the upper surface of the gate electrode 12 is exposed. In this manner, the upper surface of the insulating film 13 becomes flush with the upper surface of the gate electrode 12, so that the surface is flattened.

Then, a comb-shaped pattern P having a lyophilic surface S₁, for example, as shown in FIG. 3, is formed on the surfaces of the insulating film 13 and the gate electrode 12 flattened as described above. As necessary, an insulating film serving as a part of a gate insulating film may be formed on the insulating film 13 and the gate electrode 12 before the comb-shaped pattern P is formed.

Next, as shown in FIG. 16, the substrate 11 provided with the gate electrode 12 and the insulating film 13 is introduced into the chamber 21 of the film-forming apparatus and is placed on the holder 25. Subsequently, the exhaust pipe 24 is closed, and the chamber 21 and the solvent tank 23 are sealed. Thereafter, for example, a gas 28, e.g., nitrogen (N₂), is introduced into the solvent tank 23 from the gas introduction pipe 27. Consequently, a vapor 29 containing the auxiliary solvent 26 is supplied to the chamber 21 from the solvent tank 23 through the connection pipe 22 and, thereby, the inside of this chamber 21 comes into an environment filled with the vapor 29. The temperature of the substrate 11 is set to be T_{g} shown in FIG. 2 by using the holder 25. It is preferable that the temperature of the auxiliary solvent 26 is also set to be T_{g}, as necessary, by using an oil bath or the like. Consequently, the vapor pressure P in the inside of the chamber 21 becomes a saturated vapor pressure at the temperature of T_{g}, so that the liquid phase (organic solution 18) and the gas phase (vapor) are brought into an equilibrium state. The same goes for the liquid phase (auxiliary solvent 26) and the gas phase (vapor) in the inside of the solvent tank 23.

Meanwhile, an organic solution 18 is prepared, in which an organic semiconductor and an organic insulator having a specific gravity larger than that of the organic semiconductor are dissolved in a solvent having a specific gravity smaller than the specific gravities of these organic semiconductor and organic insulator. As for the solvent, the known solvent in the related art can be used and is selected as necessary. Concrete examples include at least one of xylene, p-xylene, mesitylene, toluene, tetralin, anisole, benzene, 1,2-dichlorobenzene, o-dichlorobenzene, cyclohexane, and ethylcyclohexane.

As shown in FIG. 15A and FIG. 16, the thus prepared organic solution 18 is supplied to the insulating film 13 and the gate electrode 12. Subsequently, as shown in FIG. 15B, the organic insulator in this organic solution 18 is sunk, so as to form an insulating film 14.

Then, in the same manner as the above-described growing method, the solvent in the organic solution 18 is vaporized while the temperature of the organic solution 18 is kept at T_{g}, so that a crystal nucleus is formed from the organic solution 18 stored on the comb tooth portion P₂, a crystal C grown from this crystal nucleus blocks the comb tooth portion P₂ of the connection portion to the back portion P₁, and only one crystal C involved in blocking begins to grow in the organic solution 18 stored on the back portion P₁. At this time, regarding the organic solution 18 stored on the back portion P₁, the surface has the highest degree of supersaturation. Therefore, growth of the crystal proceeds at the surface of the organic solution 18, the crystal grows in a lateral direction while floating in the organic solution 18 and, thereby, an organic semiconductor single crystal thin film 15 grows. Subsequently, at the point in time when the solvent of the organic solution 18 stored on the back portion P₁ runs out through vaporization, this organic semiconductor single crystal thin film 15 comes into contact with the surface of the gate insulating film 14.

Next, as necessary, the thus formed organic semiconductor single crystal thin film 15 is patterned into a predetermined shape through etching or the like and, thereafter, a source electrode 16 and a drain electrode 17 are formed on the resulting organic semiconductor single crystal thin film 15 by the known method in the related art.

In this manner, a desired top contact-bottom gate type organic transistor is produced.

As described above, the organic semiconductor single crystal thin film 15 is obtained by the crystal growing in the lateral direction while floating in the organic solution 18. An actual example showing this will be described.

As shown in FIG. 17A and FIG. 17B, a plurality of fine-line patterns 32 made from Au were formed parallel to each other on a substrate 31 provided with the insulating film made from an organic insulator on the surface. Thereafter, growth was effected by the above-described growing method through the use of an organic solvent in which C₂ Ph-PXX was dissolved in a solvent. Here, FIG. 17A is a plan view and FIG. 17B is a sectional view.

As shown in FIGS. 17A and 17B, a C₂ Ph-PXX single crystal thin film 33 was grown on the fine-line pattern 32. FIG. 18A shows a cross-sectional transmission electron micrograph in the vicinity of the second fine-line pattern 32 from left in FIG. 17B. In FIG. 18A, a void (Void) surrounded by this fine-line pattern 32, the C₂ Ph-PXX single crystal thin film 33, and the substrate 31 is observed on the left of the fine-line pattern 32. Furthermore, FIG. 18B shows a cross-sectional transmission electron micrograph of a portion to the left of the first fine-line pattern 32 from left in FIG. 17B. In FIG. 18B, a void (Void) surrounded by the C₂ Ph-PXX single crystal thin film 33 and the substrate 31 is observed on the left of the fine-line pattern 32.

The size of the C₂ Ph-PXX single crystal thin film 33 in the plane was about 100 μm, and the thickness was about 0.7 μm. Consequently, the ratio of the growth rate in the lateral direction of the C₂ Ph-PXX single crystal thin film 33 to the growth rate in the vertical direction was about 140. It can be said from this result that the C₂ Ph-PXX single crystal thin film 33 grows in the lateral direction.

As described above, according to this first embodiment, the organic semiconductor single crystal thin film 15 can be grown on the gate insulating film 14 without exposing the surface of the gate insulating film 14 to the air on the way. Therefore, the interface between the organic semiconductor single crystal thin film 15 and the gate insulating film 14 can be made good. Consequently, the carrier mobility of the organic semiconductor single crystal thin film 15 can be increased sufficiently and a high-mobility, high-performance organic transistor can be realized.

### 2. Second Embodiment

### Method for Manufacturing Organic Transistor

FIG. 19A, FIG. 19B, FIG. 19C, and FIG. 19D show a method for manufacturing an organic transistor according to a second embodiment.

As shown in FIG. 19A, initially, in the same manner as that in the first embodiment, a large number of gate electrodes 12 are formed into the shape of an array on one principal surface of a substrate 11. An insulating film 13 is filled into the portions between the gate electrodes 12.

Subsequently, as shown in FIG. 19B, in the same manner as that in the first embodiment, an organic solution 18 is supplied to the one principal surface provided with the gate electrodes 12 and the insulating film 13 of the substrate 11.

Then, as shown in FIG. 19C, in the same manner as that in the first embodiment, a gate insulating film 14 is formed on the gate electrodes 12 by sinking an organic insulator in the organic solution 18.

Next, as shown in FIG. 19D, in the same manner as that in the first embodiment, an organic semiconductor single crystal thin film 15 is grown on the gate insulating film 14.

Thereafter, the organic semiconductor single crystal thin film 15 is patterned through etching, so as to be divided into regions having predetermined shapes including the individual gate electrodes 12, and then, a source electrode 16 and a drain electrode 17 are formed on each organic semiconductor single crystal thin film 15.

In this manner, a plurality of organic transistors are formed into the shape of a large number of arrays.

According to this second embodiment, the same advantages as those in the first embodiment can be obtained.

### 3. Third Embodiment

### Method for Manufacturing Organic Transistor

In the method for manufacturing an organic transistor according to a third embodiment, an organic solution 18 is prepared as described below. That is, a first organic solution is prepared by dissolving an organic semiconductor into a first solvent having a specific gravity smaller than the specific gravity of this organic semiconductor and, in addition, a second organic solution is prepared by dissolving an organic insulator into a second solvent having a specific gravity smaller than the specific gravity of this organic insulator. The specific gravity of the first solvent is smaller than the specific gravity of the second solvent. Therefore, the first solvent and the second solvent are not dissolved with each other. In this regard, as for the second solvent, a solvent which is vaporized (volatilized) faster than the first solvent is used. These first organic solvent and second organic solvent are mixed with each other and the mixture is used as the organic solution 18. The resulting organic solution 18 is agitated vigorously and is applied or printed on the gate electrodes 12. As for the method for applying the organic solution 18, a spin coating method and the like are mentioned. Examples of methods for printing the organic solution 18 include a screen printing method, an ink-jet printing method, an off-set printing method, a reverse off-set printing method, a gravure printing method, and a microcontact method. Examples of methods for applying or printing the organic solution 18 also include various coating methods, e.g., an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, a calender coater method, and a dipping method.

In the organic solution 18 applied or printed on the gate electrodes 12, the second organic solution in which the organic insulator is dissolved in the second solvent is formed as a lower layer, the second organic solution in which the organic semiconductor is dissolved in the first solvent is formed as an upper layer, and the two solutions are phase-separated. Initially, a gate insulating film 14 is formed on the gate electrodes 12 through sinking of the organic insulator in the second organic solution. Subsequently, the second solvent was vaporized and, thereafter, an organic semiconductor single crystal thin film 15 is grown on the gate insulating film 14 in the same manner as that in the first embodiment.

This third embodiment is the same as the first embodiment except those described above.

According to this third embodiment, the same advantages as those in the first embodiment can be obtained.

Up to this point, the embodiments have been explained concretely. However, the present disclosure is not limited to the above-described embodiments.

For example, the numerical values, the structures, the configurations, the shapes, the materials, and the like mentioned in the above-described embodiments are no more than examples, and numerical values, structures, configurations, shapes, materials, and the like different from them may be employed, as necessary.

Meanwhile, the present disclosure may employ the following configurations.

In one embodiment, an organic single crystal thin film is provided and includes an organic single crystal formed on a substrate across a boundary between a first region of the substrate and a second region of the substrate that is adjacent to the first region, the first region having a different shape or size than the second region. In an embodiment, the first region and second region have a lyophilic surface. In an embodiment, the first region and the second region are surrounded by a third region having a lyophobic surface. In an embodiment, the first region has a larger surface area than the second region. In an embodiment, the first region has a rectangular shape having a first width, and the second region including a first portion having a rectangular shape and having a second width that is less than the first width. In an embodiment, the second region has a width ranging from about 5 to 10 μm. In an embodiment, the second region further includes a second portion having a rectangular shape that is inclined at an angle relative to the first portion. In an embodiment, the organic single crystal has a crystal width that is greater than a width of the second region and less that a width of the first region. In an embodiment, the organic single crystal has an orthorhombic structure including facet angles of about 82 and 98 degrees. In an embodiment, the organic single crystal has a rotation angle ranging from about −38 degrees to −58 degrees with respect to the boundary between the first region of the substrate and the second region of the substrate. In an embodiment, the organic single crystal is an organic semiconducting single crystal or an organic insulating single crystal.

In another embodiment, a method of manufacturing an organic single crystal thin film is provided. The method includes forming an organic single crystal across a boundary between a first region of the substrate and a second region of the substrate that is adjacent to the first region, the first region having a different shape or size than the second region. In an embodiment, forming the organic single crystal includes: applying an solution to the first region and the second region, the solution including an organic semiconductor dissolved in a solvent; and evaporating a portion of the solution to initiate crystal growth of the organic single crystal. In an embodiment, the first surface region and the second surface region have a lyophilic characteristic relative to a third surface region of the substrate that surrounds the first region and the second region. In an embodiment, a volume of the solution applied to the first region is greater than a volume of the solution applied to the second region. In an embodiment, crystal growth of the organic single crystal is initiated in the second region, and the crystal growth continues into the first region across the boundary between the first region and the second region. In an embodiment, the first region has a larger surface area than the second region. In an embodiment, the first region has a rectangular shape having a first width, and the second region including a first portion having a rectangular shape and having a second width that is less than the first width. In an embodiment, the second region has a width ranging from about 5 to 10 μm. In an embodiment, the second region further includes a second portion having a rectangular shape that is inclined at an angle relative to the first portion. In an embodiment, the organic semiconductor single crystal has a crystal width that is greater than a width of the second region and less that a width of the first region. In an embodiment, the organic single crystal is an organic semiconducting single crystal or an organic insulating single crystal. In an embodiment, the solution further includes an organic insulator having a higher specific gravity than that of the organic semiconductor. In an embodiment, the solution is a two-component mixed system containing the organic semiconductor and an organic insulator, the method further comprising effecting a two-phase separation of the solution between the organic semiconductor and organic semiconductor by quenching the solution from a higher temperature to a lower temperature.

In another embodiment, an organic single crystal thin film array is provided, and includes a plurality of organic single crystals arranged in an array, each organic single crystal being formed across boundaries between a first region of a substrate, and second regions of the substrate that are adjacent to the first region, the first region having a different shape or size than each of the respective second regions. In an embodiment, the first region and second regions have a lyophilic surface. In an embodiment, the first region and the second regions are surrounded by a third region having a lyophobic surface. In an embodiment, the first region has a larger surface area than a sum of the surface areas of the second regions. In an embodiment, the first region and the second regions form a comb-shaped region, the first region having a rectangular shape, and the second regions each including first portions having rectangular shapes extending from one side of the first region to form said comb-shaped region. In an embodiment, the organic single crystals each have a crystal width that is greater than a width of the corresponding second region and less that a width of the first region. In an embodiment, each of the second regions have a width ranging from about 5 to 10 μm. In an embodiment, the second regions further include second portions having a rectangular shape that are inclined at an angle relative to the respective first portions. In an embodiment, each of the organic single crystals have an orthorhombic structure including facet angles of about 82 and 98 degrees. In an embodiment, each of the organic single crystals have a rotation angle with respect to the respective boundaries between the first region of the substrate and the second regions of the substrate, and crystals having a rotation angle ranging from about −38 to −58 degrees with respect to the respective boundaries are predominant. In an embodiment, the organic single crystals are organic semiconducting single crystals or organic insulating single crystals.

In another embodiment, a method of manufacturing an organic single crystal thin film array is provided. The method includes forming a plurality of organic single crystals across boundaries between a first region of a substrate, and second regions of the substrate that are adjacent to the first region, the first region having a different shape or size than each of the respective second regions. In an embodiment, forming the plurality of organic single crystals includes: applying an solution to the first region and the second regions, the solution including an organic semiconductor dissolved in a solvent; and evaporating a portion of the solution to initiate crystal growth of the organic single crystals. In an embodiment, the first surface region and the second surface regions have a lyophilic characteristic relative to a third surface region of the substrate that surrounds the first region and the second regions. In an embodiment, a volume of the solution applied to the first region is greater than a total volume of the solution applied to the second regions. In an embodiment, crystal growth of the organic single crystals is initiated in the second regions, and the crystal growth continues into the first region across the boundaries between the first region and the respective second regions. In an embodiment, the first region has a larger surface area than a sum of the surface areas of the second regions. In an embodiment, the first region and the second regions form a comb-shaped region, the first region having a rectangular shape, and the second regions each including first portions having rectangular shapes extending from one side of the first region to form said comb-shaped region. In an embodiment, the organic single crystals each have a crystal width that is greater than a width of the corresponding second region and less that a width of the first region. In an embodiment, each of the second regions have a width ranging from about 5 to 10 μm. In an embodiment, the second regions further include second portions having a rectangular shape that are inclined at an angle relative to the respective first portions In an embodiment, the organic single crystals are organic semiconducting single crystals or organic insulating single crystals. In an embodiment, the solution further includes an organic insulator having a higher specific gravity than that of the organic semiconductor. In an embodiment, the solution is a two-component mixed system containing the organic semiconductor and an organic insulator, and the method further includes effecting a two-phase separation of the solution between the organic semiconductor and organic semiconductor by quenching the solution from a higher temperature to a lower temperature.

In another embodiment, a semiconductor device in provided and includes: a gate electrode disposed on a substrate; an insulating film formed on a portion of the substrate outside of the gate electrode; and an organic single crystal thin film formed on the gate electrode and the insulating film, the organic single crystal thin film including an organic single crystal formed on a substrate across a boundary between a first region of the substrate and a second region of the substrate that is adjacent to the first region, the first region having a different shape or size than the second region. In an embodiment, the first region and second region have a lyophilic surface. In an embodiment, the first region and the second region are surrounded by a third region having a lyophobic surface. In an embodiment, the first region has a larger surface area than the second region. In an embodiment, the first region has a rectangular shape having a first width, and the second region including a first portion having a rectangular shape and having a second width that is less than the first width. In an embodiment, the second region has a width ranging from about 5 to 10 μm. In an embodiment, the second region further includes a second portion having a rectangular shape that is inclined at an angle relative to the first portion. In an embodiment, the organic single crystal has a crystal width that is greater than a width of the second region and less that a width of the first region. In an embodiment, the organic single crystal has an orthorhombic structure including facet angles of about 82 and 98 degrees. In an embodiment, the organic single crystal has a rotation angle ranging from about −38 degrees to −58 degrees with respect to the boundary between the first region of the substrate and the second region of the substrate. In an embodiment, the organic single crystal is an organic semiconducting single crystal or an organic insulating single crystal.

In another embodiment, a crystal growth substrate is provided and includes a first surface region configured to gather an amount of liquid relative to a surrounding second surface region due to a liquiphillic characteristic of the first surface region relative to a surrounding second surface region. In this embodiment, the first surface region includes first and second sub-regions each configured to retain a different volume of liquid per unit surface area of the respective sub-region. In an embodiment, the first sub-region has a rectangular shape having a first width, and the second sub-region including a first portion having a rectangular shape and having a second width that is less than the first width. In an embodiment, the second sub-region has a width ranging from about 5 to 10 μm. In an embodiment, the second sub-region further includes a second portion having a rectangular shape that is inclined at an angle relative to the first portion. In an embodiment, the organic single crystal has a crystal width that is greater than a width of the second sub-region and less that a width of the first sub-region. In an embodiment, the liquiphillic characteristic of the first surface region is at least substantially uniform across the first and second sub-regions.

In another embodiment, a method of distributing a liquid is provided. The method includes applying the liquid to a substrate and allowing the liquid to gather in a first surface region of the substrate, the first surface region having a liquiphillic characteristic relative to a surrounding second surface region of the substrate. In this embodiment, the first surface region includes first and second sub-regions each configured to retain a different volume of liquid per unit surface area of the respective sub-region. In an embodiment, the liquiphillic characteristic of the first surface region is at least substantially uniform across the first and second sub-regions.

In another embodiment, a method of concentrating a liquid solution is provided. The method includes applying the solution to a substrate and allowing the liquid to gather in a first surface region of the substrate, the first surface region having a liquiphillic characteristic relative to a surrounding second surface region of the substrate, the first surface region including first and second sub-regions each configured to retain a different volume of liquid per unit surface area of the respective sub-region. The method also includes evaporating a portion of the solution to increase concentrations of the solution retained in the sub-regions at different rates corresponding to the volume of liquid per unit surface area ratios of the respective sub-regions. In an embodiment, the liquiphillic characteristic of the first surface region is at least substantially uniform across the first and second sub-regions. In an embodiment, the method includes further evaporating the solution to initiate crystal growth of an organic single crystal in the second sub-region.

In another embodiment, a method for manufacturing an organic semiconductor element is provided. The method includes: supplying an unsaturated organic solution, in which an organic semiconductor and an organic insulator are dissolved in a solvent, to a growth control region and at least one nucleation control region of a base substance including, on one principal surface, the growth control region having a lyophilic surface and the nucleation control region disposed on one side of this growth control region while being coupled to this growth control region; forming an insulating film made from the organic insulator by sinking the organic insulator in the organic solution on the one principal surface of the base substance; and growing an organic semiconductor single crystal thin film made from the organic semiconductor on the insulating film by vaporizing the solvent in the organic solution. In an embodiment, the solvent in the organic solution is vaporized in such a way that the state of the organic solution in the growth control region is in a metastable state between a solubility curve and a supersolubility curve of the solubility-supersolubility diagram of the organic solution and the state of the organic solution in the nucleation control region is in an unstable region under the supersolubility curve of the solubility-supersolubility diagram. In an embodiment, the organic solution is kept at a constant temperature. In an embodiment, the specific gravity of the organic insulator is larger than the specific gravity of the organic semiconductor. In an embodiment, the organic solution is made from a first organic solution, in which the organic semiconductor is dissolved in a first solvent, and a second organic solution, in which the organic insulator is dissolved in a second solvent, and the specific gravity of the first solvent is smaller than the specific gravity of the second solvent. In an embodiment, the growth control region has the shape of a rectangle and the nucleation control region has the shape of a rectangle which is disposed on one side of the growth control region perpendicularly to this side and which is smaller than the growth control region. In an embodiment, the organic semiconductor element is an organic transistor, a gate electrode is formed on the one principal surface of the base substance, the insulating film serving as a gate insulating film is formed on this gate electrode, and the organic semiconductor single crystal thin film serving as a channel layer is grown on the insulating film.

In another embodiment, an organic semiconductor element is produced by executing: supplying an unsaturated organic solution, in which an organic semiconductor and an organic insulator are dissolved in a solvent, to a growth control region and at least one nucleation control region of a base substance including, on one principal surface, the growth control region having a lyophilic surface and the nucleation control region disposed on one side of this growth control region while being coupled to this growth control region; forming an insulating film made from the organic insulator by sinking the organic insulator in the organic solution on the one principal surface of the base substance; and growing an organic semiconductor single crystal thin film made from the organic semiconductor on the insulating film by vaporizing the solvent in the organic solution.

In another embodiment, an electronic apparatus comprising the organic semiconductor element is produced by executing: supplying an unsaturated organic solution, in which an organic semiconductor and an organic insulator are dissolved in a solvent, to a growth control region and at least one nucleation control region of a base substance including, on one principal surface, the growth control region having a lyophilic surface and the nucleation control region disposed on one side of this growth control region while being coupled to the growth control region; forming an insulating film made from the organic insulator by sinking the organic insulator in the organic solution on the one principal surface of the base substance; and growing an organic semiconductor single crystal thin film made from the organic semiconductor on the insulating film by vaporizing the solvent in the organic solution.

### REFERENCE SIGNS LIST

11 substrate
12 gate electrode
13 insulating film
14 gate insulating film
15 organic semiconductor single crystal thin film
16 source electrode
17 drain electrode
18 organic solution

1. An organic single crystal thin film comprising:
an organic single crystal formed on a substrate across a boundary between a first region of the substrate and a second region of the substrate that is adjacent to the first region, the first region having a different shape or size than the second region.

2. The organic single crystal film according to claim 1, wherein the first region has a larger surface area than the second region.

3. The organic single crystal film according to claim 1, wherein the first region has a rectangular shape having a first width, and the second region including a first portion having a rectangular shape and having a second width that is less than the first width.

4. The organic single crystal film according to claim 3, wherein the second region has a width ranging from about 5 to 10 μm.

5. The organic single crystal film according to claim 3, wherein the second region further includes a second portion having a rectangular shape that is inclined at an angle relative to the first portion.

6. The organic single crystal film according to claim 1, wherein the organic single crystal has a crystal width that is greater than a width of the second region and less that a width of the first region.

7. The organic single crystal film according to claim 1, wherein the organic single crystal has an orthorhombic structure including facet angles of about 82 and 98 degrees.

8. The organic single crystal film according to claim 6, wherein the organic single crystal has a rotation angle ranging from about −38 degrees to −58 degrees with respect to the boundary between the first region of the substrate and the second region of the substrate.

9. The organic single crystal film according to claim 1, wherein the organic single crystal is an organic semiconducting single crystal or an organic insulating single crystal.

10. An organic single crystal thin film array comprising:
a plurality of organic single crystals arranged in an array, each organic single crystal being formed across boundaries between a first region of a substrate, and second regions of the substrate that are adjacent to the first region, the first region having a different shape or size than each of the respective second regions.

11. The organic single crystal film array according to claim 10, wherein the first region has a larger surface area than a sum of the surface areas of the second regions.

12. The organic single crystal film array according to claim 10, wherein the first region and the second regions form a comb-shaped region, the first region having a rectangular shape, and the second regions each including first portions having rectangular shapes extending from one side of the first region to form said comb-shaped region.

13. The organic single crystal film array according to claim 10, wherein the organic single crystals each have a crystal width that is greater than a width of the corresponding second region and less that a width of the first region.

14. The organic single crystal film array according to claim 10, wherein each of the second regions have a width ranging from about 5 to 10 μm.

15. The organic single crystal film array according to claim 12, wherein the second regions further include second portions having a rectangular shape that are inclined at an angle relative to the respective first portions.

16. The organic single crystal film array according to claim 10, wherein each of the organic single crystals have an orthorhombic structure including facet angles of about 82 and 98 degrees.

17. The organic single crystal film array according to claim 16, wherein each of the organic single crystals have a rotation angle with respect to the respective boundaries between the first region of the substrate and the second regions of the substrate, and crystals having a rotation angle ranging from about −38 to −58 degrees with respect to the respective boundaries are predominant.

18. The organic single crystal film array according to claim 10, wherein the organic single crystals are organic semiconducting single crystals or organic insulating single crystals.

19. A semiconductor device comprising:
a gate electrode disposed on a substrate;
an insulating film formed on a portion of the substrate outside of the gate electrode; and
an organic single crystal thin film formed on the gate electrode and the insulating film, the organic single crystal thin film including an organic single crystal formed on a substrate across a boundary between a first region of the substrate and a second region of the substrate that is adjacent to the first region, the first region having a different shape or size than the second region.

20. The semiconductor device according to claim 19, wherein the first region has a rectangular shape having a first width, and the second region including a first portion having a rectangular shape and having a second width that is less than the first width.
